(19) United States
(12) Patent Application Publication
(10) Pub. No.: US 2008/0138721 A1
(43) Pub. Date: Jun. 12, 2008

(54) Substrate and method of fabricating the same

(75) Inventors: Yasuo Hiramoto, Kanagawa (JP); Kousuke Nakajima, Kanagawa (JP); Yoshiyuki Owari, Kanagawa (JP); Toshikazu Oshiro, Kanagawa (JP); Shinji Takagi, Kanagawa (JP)

Correspondence Address: SQUIRE, SANDERS & DEMPSEY L.L.P., 8000 TOWERS CRESCENT DRIVE, 14TH FLOOR, VIENNA, VA, 22182-2700, US

(73) Assignees: Ohara Inc.; OPC Corporation

(21) Appl. No.: 11/987,631

(22) Filed: Dec. 3, 2007

(30) Foreign Application Priority Data
Dec. 6, 2006 (JP) 2006-329687

(51) Int. Cl. G03F 1/00

(52) U.S. Cl. 430/5

(57) ABSTRACT

An object of the present invention is to provide a method of fabricating a substrate, and the like which excels in flatness, ten-point average roughness and surface roughness of substrates and flattens and smoothes the substrate surface. The method of fabricating a substrate includes a step of correcting flatness, a step of correcting surface unevenness in which the substrate surface is polished by means of a polishing pad with a hardness defined by JIS K 6253 of 70 or more, and a step of finishing surface roughness, to therefore achieve the above objectives. Such a substrate can be used for masks and mirrors of semiconductor exposure, discs for flying height tests of the hard-disk magnetic heads, and pharmaceutical test preparation, and the like.

This application is based on and claims the benefit of priority from Japanese Patent Application No. 2006-329687, filed on 6 Dec. 2006, the content of which is incorporated herein by reference.

### BACKGROUND OF THE INVENTION

1. Field of the Invention

The present invention relates to methods of fabricating a substrate used for masks and mirrors for semiconductor exposure, discs for flying height tests of hard-disk magnetic heads and pharmaceutical test preparations, and specifically to polishing of substrates.

2. Related Art

Glass and crystallized glass have been used as substrate materials for a variety of purposes and are often required to have a flat and smooth surface profile. Particularly in recent years, substrates with high-accuracy surface profiles have been demanded for masks and mirrors of semiconductor exposure.

For example, mirrors and photomask substrates used for Extreme Ultraviolet Lithography (EUVL) as a next generation semiconductor exposure technology are required to be resistant to heat deformation with an appropriate surface profile for preventing degradation of the exposure quality. Therefore, glass or crystallized glass having low expansion characteristics has been applied as a substrate material of mirrors and photomask substrates used for EUVL, and the surface profile thereof is required to be extremely flat and smooth on the basis of specifications.

Furthermore, recording densities have rapidly increased in the market of magnetic discs of hard disk drives in recent years. With an increase in the recording density, the distance between the magnetic head and the magnetic disc in the hard disk drive apparatus, that is to say the flying height of the magnetic head, is being decreased. In recent years, the flying height of the magnetic head has been approaching approximately 10 nm to 50 nm. The flying height of the magnetic head is measured from the interference of incoming light and the like, by using a transparent imitation disc as a substitute for the magnetic disc in the flying tests of the magnetic heads conducted by disc manufacturers or hard disc drive apparatus manufacturers. Such transparent imitation discs are also required to have high flatness and smoothness.

In the pharmaceutical market, automation of inspection devices and sample miniaturization are progressing in order to improve the inspection efficiency of the pharmaceutical samples and to make batch processing of large quantities of sample inspections possible. If the dimensions of dripped samples is on the order of micrometers, it is possible that an uneven surface form of the substrate supporting the sample can have adverse effects on the ability to keep the sample still. Demand for high-precision surface profiles is increasing for substrates of pharmaceutical inspections used for the inspection of pharmaceutical samples in order to prevent faulty blending of dripped samples.

Substrates with an extremely flat and smooth surface profile are demanded in various other markets, and methods for fabricating such substrates are being studied.

As such, a local processing technique, in which the surface profile of a substrate is measured in advance and a portion to be removed is changed locally corresponding to the height of the convex portion thereof, has been developed as a technique to realize high-level flatness. For example, the MRF (Magneto-Rheological Finishing) method is used as a local processing technique in Japanese Unexamined Patent Publication No. 2006-119624. In particular, polishing performance is improved by cleaning the surface of substrates for mask blanks using a cleaning liquid containing a strong acid after polishing the surface of substrates for mask blanks using a magnetic polishing slurry with abrasive polishing particles contained in the iron-containing magnetic fluid.

### SUMMARY OF THE INVENTION

The local processing techniques typically represented by the MRF processing method as disclosed in Japanese Unexamined Patent Publication No. 2006-119624 improves flatness, however, since polishing is performed while the processing rates or portions to be removed are changed locally, uneven components measured in a wavelength band on the level of a few millimeters level tend to be large. Even in the case when a step of finish polishing is performed afterwards, the uneven components are not ameliorated and the required high-accuracy surface profile cannot be obtained although flatness measured in the wavelength band of a level equivalent to the dimensions of the substrate and surface roughness measured in the wavelength band on the level of a few micrometers are appropriate.

Therefore, it has been extremely difficult to obtain substrates having a high-accuracy surface profile with flatness, unevenness and surface roughness all being appropriate in conventional art.

The present invention has been made to solve above-mentioned problems, and an object of the present invention is to provide a substrate having a high-accuracy surface profile with flatness, unevenness and surface roughness all being appropriate, and a method of fabricating such substrates in the technological fields where substrates having a high-accuracy surface profile are demanded.

The inventors have found that the above problems can be solved by performing a step of correcting the surface unevenness and a step of surface roughness finishing, after performing the step of correcting the flatness, and accomplished the invention. Specifically, the present invention provides the following.

The first aspect of the invention is a method of fabricating a substrate comprising a step of correcting flatness, a step of correcting surface unevenness wherein the substrate surface is polished by means of a polishing pad with a hardness defined by JIS K 6253 of 70 or more, and a step of finishing surface roughness.

The second aspect of the invention comprises the method of fabricating a substrate of the first aspect, wherein the main material of the polishing pad is a resin, an unwoven fabric, or an unwoven fabric impregnated with a resin.

The third aspect of the invention comprises the method of fabricating a substrate of the second aspect wherein inorganic particles are dispersed in the main material of the polishing pad.

The fourth aspect of the invention comprises the method of fabricating a substrate of one of the first to third aspects wherein the bulk density of the polishing pad is 0.2 g/cm³ or more.

The fifth aspect of the invention comprises the method of fabricating a substrate according to one of the first to fourth aspects wherein a polishing agent with an average particle diameter of 1 μm or less is used in the step of correcting surface unevenness.

The sixth aspect of the invention comprises the method of fabricating a substrate according to one of the first to fifth aspects wherein the ten-point average roughness of the substrate surface after the step of correcting surface unevenness is 6.5 nm or less.

The seventh aspect of the invention comprises the method of fabricating a substrate according to one of the first to sixth aspects wherein the flatness of the substrate surface after the step of correcting flatness is 1,000 nm or less.

The eighth aspect of the invention comprises the method of fabricating a substrate according to one of the first to seventh aspects wherein polishing is performed so that the surface load of the substrate surface is 80 g/cm² or less, in the step of finishing surface roughness.

The ninth aspect of the invention comprises the method of fabricating a substrate according to one of the first to eighth aspects wherein the step of correcting flatness is a step of polishing the substrate surface by means of a magnetic fluid containing abrasive polishing particles.

The tenth aspect of the invention comprises the method of fabricating a substrate according to one of the first to ninth aspects wherein the substrate is a glass or a glass ceramic.

The eleventh aspect of the invention comprises a substrate obtained by the method of fabricating a substrate according to one of the first to tenth aspects have at least one surface having a surface profile with a flatness of 1,000 nm or less, a ten-point average roughness of 10 nm or less and a Rms of 1 nm or less.

The twelfth aspect of the invention comprises a semiconductor exposure mask using a substrate fabricated by the method of fabricating a substrate according to one of the first to tenth aspects of the invention.

The thirteenth aspect of the invention comprises a semiconductor exposure mirror using a substrate fabricated by the method of fabricating a substrate according to one of the first to tenth aspects.

The fourteenth aspect of the invention comprises a disc for flying height testing of hard-disk magnetic heads using a substrate fabricated by the method of fabricating a substrate according to one of the first to tenth aspects.

The fifteenth aspect of the invention comprises a substrate for pharmaceutical testing using a substrate fabricated by the method of fabricating a substrate according to one of the first to tenth aspects.

In the present invention, uneven components of the substrate can be removed, and a substrate having a high-accuracy surface profile where the flatness, unevenness and surface roughness are all appropriate can be obtained.

### BRIEF DESCRIPTION OF THE DRAWINGS

FIG. 1 is a schematic view showing an apparatus used in the step of correcting surface unevenness and the step of finishing surface roughness.

FIG. 2 is a sectional schematic view showing an apparatus used in the step of correcting surface unevenness and the step of finishing surface roughness.

### DETAILED DESCRIPTION OF THE INVENTION

The method of fabricating a substrate according to the present invention is characterized by including a step of correcting flatness, a step of correcting surface unevenness in which the substrate surface is polished by means of a polishing pad with a hardness defined by JIS K 6253 of 70 or more, and a step of finishing surface roughness.

The hardness of the polishing pad stated herein is an average value (rounded off to the nearest whole number) of the hardness values defined by JIS K 6253 measured at four random points within the surface of the polishing pad. Further, measurement positions are determined as follows in the case of donut-shaped polishing pads. When the outer diameter of the polishing pad is defined as “D” and the opening diameter is defined as “d”, a random point on the circumference with a diameter of (D+d)/2 and three points located respectively at 90°, 180° and 270° in the clockwise direction from said random point are determined as measurement positions.

Furthermore, flatness is defined as the difference in height between the highest and lowest points of the surface profile measured from the arbitrary base level of the substrate surface in the measurement area with a S₂/S₁ value of 85% or more (S₂ shares the same center of gravity with S₁ and has a form similar to that of S₁) while S₁ being an area of the substrate and S₂ being a measurement area. The flatness is the value obtained by means of a wavelength-changed light source as a semiconductor laser and a measurement device based on the Fourier transform phase shift method with a resolution of 0.3 mm/pixel. In particular, flatness can be measured by means of a VeriFire-AT manufactured by Zygo, for example.

In addition, in the case of a photomask substrate used for EUVL, the measurement area preferably has a dimension of 142 mm×142 mm relative to the square substrate with a dimension of 152 mm×152 mm.

The ten-point average roughness stated herein is defined as the difference between the average height of the highest to the fifth highest peaks of the surface profile measured from the arbitrary base level of the substrate surface and the average height of the lowest to the fifth lowest valleys of the surface profile measured from the arbitrary base level of the substrate surface to the bottom of the surface profile in the measurement area with a view angle of 2.8 mm×2.11 mm. The ten-point average roughness can be obtained by means of a scanning white light microscope using an objective lens of 2.5× with a system magnification of 1.0× with no filter. Specifically, the ten-point average roughness can be measured by means of the NewView manufactured by Zygo.

The Rms stated herein is defined as a square root of an average value of the square of the deviation from the arbitrary base level to the surface in a measurement area with a view angle of 10 μm×10 μm and can be obtained by means of an atomic force microscope. Specifically, the Rms can be measured for example, by means of a Nano Scope IIIa/D-3000 manufactured by Digital Instruments.

Embodiments of the method of fabricating a substrate according to the present invention will be described in detail below. It should be noted that the present invention is not limited to the embodiments described below and variations can be added accordingly within the scope of the present invention. Meanwhile, the intention of the present invention is not limited although the description may be omitted where there is an overlap.

For the convenience of description, the method of fabricating a substrate in which a step of correcting surface unevenness is performed after the step of correcting flatness followed by a step of finishing surface roughness will be described first, however, the present invention is not limited to the above, and other steps may be performed between or before and after each step depending on the material, and the like of substrates.

Moreover, the nature of the substrates is not limited, and various known substrates such as metallic substrates, glass, glass ceramic, and the like may be used, for example.

Prior to the step of correcting flatness, steps of slice cutting, grinding, lapping and rough grinding may be performed accordingly.

The slice cutting step is a step in which a desired surface profile is obtained by cutting by means of a cutter made from diamond or hard metal, etc. or by rotary grinding.

The grinding step is a step in which the substrate surface is ground to bring it closer to the desired profile, and the warping over the substrate is corrected to produce a substrate with an approximately flat surface. In this grinding step, grinding is performed by means of a one-side processing machine using fixed abrasive particles and changing the conditions such as particle size, and grinding may be performed by steps such as a primary step, a secondary step, and the like according to the circumstances.

The lapping step is a step in which the substrate surface is further flattened after the grinding step. A polishing agent in the slurry form in which particles of carbonized silicon with a large particle diameter, alumina and the like are dispersed in water, etc. is used in the lapping step as a polishing agent with free abrasive particles. In addition, fixed abrasive particles of consolidated particles of carbonized silicon, alumina, and the like or diamonds consolidated by means of a metal bond, a resin bond, a vitrified bond, or electrodeposition to generally form a pellet are used. Furthermore, chamfering or chamfer polishing may be performed by means of a NC processing machine before/after or during lapping step.

The rough grinding step is a step in which polishing is performed by means of a two-side processing machine or an one-side processing machine by steps such as primary polishing, secondary polishing, tertiary polishing, etc. and by changing the conditions of the polishing pads and polishing agents in order to bring the surface profile closer to the desired profile.

The flatness of the substrate prior to the step of correcting flatness is preferably 1,500 nm or less, more preferably 1,400 nm or less and most preferably 1,200 nm or less for shortening the processing time of the subsequent step of correcting flatness. Moreover, if the ten-point average roughness prior to the step of correcting flatness is reduced to a certain degree, eventually obtaining a substrate with less unevenness becomes easy. Therefore, the ten-point average roughness prior to the step of correcting flatness is preferably 35 nm or less, more preferably 25 nm or less and most preferably 15 nm or less. Similarly, if the Rms prior to the step of correcting flatness is reduced to a certain degree, eventually obtaining a substrate with less Rms becomes easy. The Rms prior to the step of correcting flatness is therefore preferably 20 nm or less, more preferably 10 nm or less and most preferably 5 nm or less.

### Step of Correcting Flatness

The step of correcting flatness is a step to polish the substrate surface and to reduce flatness (further flatten) of the substrate surface. The step of correcting flatness is not particularly limited and may include any procedures as long as the substrate surface is polished to reduce the flatness of substrate surface. The step of correcting flatness is preferably performed by the MRF processing method in terms of simplicity of operation, and the like.

The MRF (Magneto-Rheological Finishing) processing method is a method of polishing in which polishing abrasive particles are contained in the magnetic fluid and the substrate surface is polished by means of the magnetic polishing slurry.

In a MRF polishing machine, an electromagnet is mounted below the surface of the rotating wheel, a magnetic fluid polishing agent is supplied therein and drawn to the surface of the rotating wheel, and the polishing target is polished locally by drawing the wheel and the polishing target close with a predetermined distance therebetween. Furthermore, a NC controller controls the relative position between the polishing target and the wheel, and the entire region of the polishing target is polished while the wheel is moved between polishing sites.

In particular, correcting flatness of the substrate by the MRF processing method is performed as follows. First, a sample for polishing rate evaluation made from the same material as that of the substrate is processed by a MRF polishing machine, and the polishing rate is calculated from the processing time and depth. The polishing rate obtained from the above calculation is entered in the MRF polishing machine. The surface profile of the substrate is then measured by means of a high-accuracy laser interference profilometer (in particular, examples include the VeriFire-AT manufactured by Zygo), etc. and the obtained data of the surface profile is entered in the MRF polishing machine.

The MRF polishing machine performs polishing while controlling the movement of the substrate so that the convex portions of the substrate surface are polished more, on the basis of the obtained data of the surface profile of the substrate and polishing rate.

The MRF polishing machine can dramatically shorten the time necessary for the following polishing by bringing the flatness of the substrate surface to the final value or a value close to the final value.

The polishing slurry used in the present invention may be a polishing slurry in which a polishing agent or an iron powder, etc. is mixed in a liquid such as water. The polishing agent may be suitably changed according to the material, and the like of substrate , and various known polishing agents such as diamond paste (D-20, D-10, etc. manufactured by QED), cerium oxide (C-20, C-10, etc. manufactured by QED), and the like can be used. These may be used alone or in combination.

The flatness of the surface of substrate after completion of the step of correcting flatness is preferably 1,000 nm or less and more preferably 700 nm or less for easy application in technological fields where substrates having a high-accuracy surface profile are demanded, and it is most preferably 400 nm or less particularly for easy application in the field of EUVL technology.

There are various methods of correcting flatness, and other examples include a method of polishing by means of a one-side processing machine. The one-side processing machine is a normal two-side polishing machine with a polishing pad attached only to the lower machine platen and polishing is performed while the polishing target is secured by its own weight or by an applied load.

### Step of Correcting Surface Unevenness

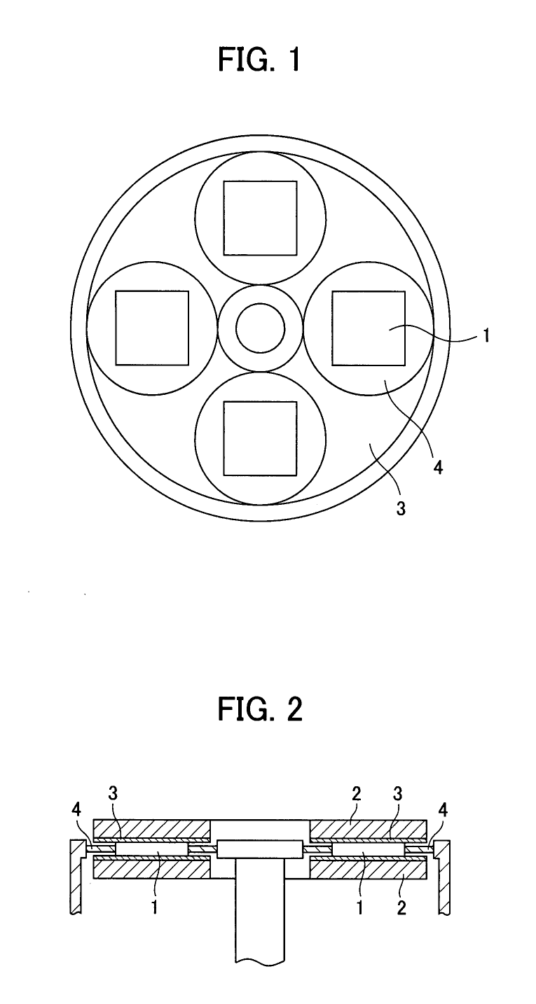

The step of correcting surface unevenness is performed after completing the step of correcting flatness. The step of correcting surface unevenness is a step to polish the surface of substrate while a polishing agent is supplied by means of a polishing pad with a hardness defined by JIS K 6235 of 70 or more (hereinafter may be referred to as “first polishing pad”). In particular, as shown in FIGS. 1 and 2, a machine platen 2 to which a polishing pad 3 with a hardness defined by JIS K 6235 of 70 or more is attached is rotated, and the surface of substrate 1 is polished while a slurry (not shown) in which a polishing agent (not shown) is dispersed is being introduced.

If the step of finishing surface roughness is performed after the step of correcting flatness without performing the step of correcting surface unevenness, although the surface roughness of the substrate is improved (flattened), it becomes difficult to effectively remove uneven components. This is because the polishing pad 3 used for the step of finishing surface roughness is normally a polishing pad with a low hardness (soft) for preventing scratches, etc. from forming on the surface, and such a polishing pad 3 is pressed by the polishing pressure, forming a profile corresponding to the uneven surface profile of substrate 1. It is possible to prevent the polishing pad from forming a profile corresponding to the uneven surface profile of substrate 1 as described above by using a polishing pad with a high hardness, thereby enabling it to effectively remove uneven components existing on the surface of substrate 1. The polishing pad 3 used for the step of correcting surface unevenness preferably has a hardness defined by JIS K 6235 of 70 or more, more preferably 80 or more, and most preferably 85 or more from the above view point.

A polishing machine which allows a relative movement between the polishing pad 3 attached to the machine platen 2 and the substrate 1 is preferably used in the step of correcting surface unevenness for making it easier to obtain a high processing accuracy to perform effective processing. Polishing machines are not particularly limited and one-side polishing machines, two-side polishing machines or the like may be used. Two-side polishing machines are preferably used because there is no need to worry about contamination, etc. of one side while the other side is being polished, and from the standpoint of processing time.

The main material of the polishing pad 3 may be suitably changed according to the material, etc. of substrate 1 being polished, and the polishing pad 3 consisting mainly of a resin such as urethane, an unwoven fabric or an unwoven fabric impregnated with a resin, and the like may be used, for example. Meanwhile, a polishing pad 3 consisting of one of these main materials alone or a polishing pad 3 consisting of a plurality of these main materials may be used.

In addition, it is preferable to use a polishing pad 3 in which inorganic particles, etc. are dispersed in the main material. Using the polishing pad 3 as mentioned above can effectively correct the unevenness of the surface of substrate 1. The inorganic particles, etc. dispersed in the main material may be suitably changed according to the material, and the like of the substrate 1 being polished, and examples include cerium oxide, zirconium oxide, and the like. These may be used alone or in combination.

The hardness of the polishing pads tends to vary within the surface of the polishing pads due to air bubbles present therein. Due to this variation in hardness, the most suitable polishing conditions such as polishing time or polishing pressure cannot be stabilized, thus possibly deteriorating the productivity. Therefore, polishing pads preferably have a high bulk density and fewer air bubbles. In particular, the bulk density of the polishing pad 3 is preferably 0.2 g/cm³ or more, more preferably 0.3 g/cm³ or more and most preferably 0.4 g/cm³ or more.

The polishing agents used in the step of correcting surface unevenness may be changed according to the materials of substrate 1, and preferred examples include colloidal silica, cerium oxide, zirconium oxide, and the like. Since the polishing agents made of colloidal silica in particular do not aggregate with each other, and have an average particle diameter smaller than that of cerium oxide, zirconium oxide, and the like, transfer of the flat profile of the polishing pad to the substrate is easy and uneven components, etc. of the surface of substrate 1 can be effectively removed. Meanwhile, polishing agents are generally dispersed in a liquid such as water and used in the form of slurry.

The average particle diameter of the polishing agents used in the step of correcting surface unevenness is preferably 1 μm or less, more preferably 500 nm or less and most preferably 100 nm or less. When the average particle diameter of the polishing agents exceeds 1 μm, the specific surface of the polishing agents becomes small, and the surface of substrate 1 may not be polished effectively.

A Coulter counter (Coulter Counter Model TA II manufactured by Coulter) is used for measurement in the method of measuring the average particle diameter of the polishing agents on the basis of the volume of the polishing agents.

In the step of correcting surface unevenness, a substrate 1 is placed on a machine platen 2 to which a polishing pad 3 with a hardness defined by JIS K 6235 of 70 or more is attached while the substrate 1 is being supported by a carrier 4. The machine platen 2 is then rotated and the surface of substrate 1 is polished while a slurry (not shown) in which a polishing agent (not shown) is dispersed is being introduced. The rotating speed of the polishing machine may be suitably changed according to the material, and the like of substrate 1. However, if the rotating speed exceeds 50 rpm, irregular rotation or vibration of the polishing machine tends to occur, thereby possibly degrading the flatness. Therefore, the upper limit of the rotating speed is preferably 50 rpm, more preferably 45 rpm and most preferably 35 rpm. Furthermore, when the rotating speed is less than 30 rpm, the processing time taken to achieve desired ten-point average roughness is lengthened, and the processing efficiency tends to be reduced. Thus, the lower limit of the rotating speed is preferably 20 rpm, more preferably 23 rpm and most preferably 25 rpm.

The rotating speed of the polishing machines stated herein is defined as the rotating speed of lower machine platen in the case of two-side polishing machines, and the upper machine platen rotates in the opposite direction of the lower machine platen at a rotating speed of one third of that of the lower machine platen. The polishing target also rotates with the carrier in the same direction as the lower machine platen at a rotating speed of one third of that of the lower machine platen.

In the step of correcting surface unevenness, the surface of the substrate 1 is preferably polished in such a way that the ten-point average roughness of the surface of substrate 1 becomes 6.5 nm or less and more preferably 6 nm or less for easy application in technological fields where substrates 1 having a high-accuracy surface profile are demanded, and the surface of substrate 1 is preferably polished so that the ten-point average roughness of the surface of substrate 1 becomes 5 nm or less particularly for easy application in the field of EUVL technology.

### Step of Finishing Surface Roughness

The step of finishing surface roughness is performed after the step of correcting surface unevenness. The step of finishing surface roughness is a step in which the surface of substrate 1 is polished so that the surface load applied to the polishing pad, which is different than the polishing pad 3 used in the step of correcting surface unevenness, and the surface of substrate 1 is 80 g/cm² or less. If the surface load is set extremely high, the flatness obtained in the step of correcting flatness tends to be reduced. Therefore, the surface load applied to the surface of substrate 1 is preferably 80 g/cm² or less, more preferably 60 g/cm² or less and most preferably 40 g/cm² or less.

It is preferable to use a polishing machine which allows a relative movement between the polishing pad 3 attached to the machine platen 2 and the substrate 1 in the step of finishing surface roughness for making it easier to obtain a high processing accuracy to perform effective processing. The polishing machine is not particularly limited and one-side polishing machines, two-side polishing machines, or the like may be used, however, two-side polishing machines are preferably used because there is no need to worry about contamination, etc. of one side while the other side is being polished, and from the standpoint of processing time.

The polishing agents used in the step of finishing surface roughness may be suitably changed according to the materials, etc. of the substrate 1, and preferred examples include cerium oxide, zirconium oxide, colloidal silica, and the like. Particularly by using cerium oxide as the polishing agent, there is less of the polishing agents eating into the substrate surface, which makes it easier to remove the polishing agents present on the substrate surface after polishing. Moreover, even though the polishing pads generally used in the step of finishing surface roughness have a surface profile with a significant quantity of uneven components, the average particle diameter of the polishing agent of cerium oxide is relatively large, and the impact of uneven components of the polishing pad on the substrate surface can be reduced, and unevenness of the substrate surface is not likely to be increased. Accordingly, a cerium oxide polishing agent is more preferably used among the polishing agents used in the finishing of surface roughness. Further, the polishing agents are generally used in the form of slurry dispersed in a liquid such as water.

The upper limit of the average particle diameter of the polishing agents used in the step of finishing surface roughness is preferably 1 μm or less, more preferably 500 nm or less and most preferably 200 nm or less. If the average particle diameter of the polishing agents exceeds 1 μm, the specific surface of the polishing agents becomes small, making it difficult to effectively polish the surface of substrate 1. The lower limit of the average particle diameter of polishing agents is preferably 100 nm or more, more preferably 120 nm and most preferably 150 nm for the purpose of easily obtaining the effect of reducing the impact of unevenness of the polishing pads on the substrate surface.

The polishing pads used in the step of finishing surface roughness (hereinafter may be called as “second polishing pad”) are different than the polishing pad 3 used in the step of correcting surface unevenness, and have a lower hardness defined by JIS K 6235 than that of the polishing pad 3 used in the step of correcting surface unevenness.

The surface roughness of the surface of substrate 1 can be easily reduced (further flattened) by polishing the surface of substrate 1 with the polishing pad (second polishing pad) with a hardness defined by JIS K 6235 of less than 70. If the surface of substrate 1 is polished with the second pad with a hardness of 70 or more, scratches are likely to appear on the surface of substrate 1.

Therefore, the hardness defined by JIS K 6235 of the second polishing pad used in the step of finishing surface roughness is preferably less than 70, more preferably 60 or less and most preferably 50 or less. The second polishing pad is preferably a suede pad with a nap layer formed on the surface of an unwoven fabric, or a suede pad with a nap layer formed on a PET sheet.

The step of finishing surface roughness can be performed by means of a polishing machine similar to the polishing machine used in the step of correcting surface unevenness as shown in FIGS. 1 and 2. The substrate surface is polished by using the second polishing pad instead of using the first polishing pad 3 while a slurry dispersed with the polishing agents is being introduced and the surface load applied to the surface of substrate 1 being 80 g/cm² or less. The rotating speed of the polishing machine in the step of finishing surface roughness may be suitably changed according to the material, and the like of substrate 1. If the rotating speed of the polishing machine exceeds 50 rpm, irregular rotation or vibration of the polishing machine tends to occur, and the flatness is subject to degradation. The upper limit of the rotating speed is therefore preferably 50 rpm, more preferably 48 rpm and most preferably 45 rpm. Moreover, since the processing requires a long time when the rotating speed is low and therefore is not efficient, the lower limit of the rotating speed of the polishing machines is preferably 20 rpm, more preferably 23 rpm and most preferably 25 rpm.

The surface profile of substrate 1 that has been processed in the step of correcting surface unevenness after completing the step of correcting flatness, and then processed in the step of finishing surface roughness after completing the step of correcting surface unevenness preferably has a flatness of 1,000 nm or less and more preferably 700 nm or less for easy application in technological fields where substrates having a high-accuracy surface profile are demanded, and the flatness of the surface of substrate 1 is most preferably 400 nm or less particularly for easy application in the field of EUVL technology. Moreover, the ten-point average roughness of the surface of substrate 1 is preferably 10 nm or less and more preferably 7 nm or less for easy application in technological fields where substrates 1 having a high-accuracy surface profile are demanded. The ten-point average roughness of the surface of substrate 1 is most preferably 6 nm or less particularly for easy application in the field of EUVL technology. Furthermore, the Rms of the surface of substrate 1 is preferably 1 nm or less and more preferably 0.5 nm or less for easy application in technological fields where substrates 1 having a high-accuracy surface profile are demanded. The Rms of the surface of substrate 1 is most preferably 0.2 nm or less particularly for easy application in the field of EUVL technology.

### Substrate Application

The substrate 1 obtained by the method of fabricating a substrate 1 according to the present invention has a surface with an excellent flatness without surface defects as a result of the above three kinds of polishing steps and is applicable for masks and mirrors of semiconductor exposure, discs for flying height tests of hard-disk magnetic heads and substrates for pharmaceutical tests. If the substrate 1 is used for the above purposes, the flatness of the substrate 1 is preferably 1,000 nm or less, more preferably 700 nm or less and most preferably 400 nm or less. The substrate 1 is preferably polished to have a ten-point average roughness of 10 nm or less, more preferably 7 nm or less and most preferably 6 nm or less. In addition, the maximum value of the surface roughness, Rmax is preferably 4 nm or less. The Rms is preferably 1 nm or less, more preferably 0.5 nm or less and most preferably 0.2 nm or less.

### EXAMPLES

The present invention will be further described in detail referring to examples, and it should be noted that the present invention is not limited to the following examples.

### Example 1

A glass (“CLEARCERAM-Z HS” manufactured by Ohara) was used as a substrate and this glass was ground by means of a diamond cutter to have dimensions of 152 mm length and 6.35 mm width. The ground substrate was processed with lapping and rough grinding. The Rms of the substrate at this time was 20,000 nm.

### [Step of Correcting Flatness]

The surface profile of the roughly ground substrate was measured by means of a VeriFire-AT manufactured by Zygo, and the result was entered in a polishing machine (Q22-Y manufactured by QED) together with the data of the polishing rate measured in advance to perform MRF processing by means of the above polishing machine for correcting flatness. The polishing slurry was a D-20 manufactured by QED.

After completing the step of correcting flatness (MRF processing method), the flatness of the substrate surface was measured and found to be 100 nm, the ten-point average roughness was 6.5 nm and the Rms was 0.82 nm.

### [Step of Correcting Surface Unevenness]

The step of correcting surface unevenness was performed after completing the step of correcting flatness. The substrate 1 was polished by means of a polishing pad with a hardness defined by JIS K 6235 of 87 while supplying colloidal silica with an average particle diameter of 80 nm that is being dispersed in water and rotating the polishing pad at 30 rpm by means of a polishing machine (12B manufactured by Tamukai) for 20 minutes. Further, a rigid urethane foam resin containing cerium oxide particles was used as a polishing pad and its bulk density was 0.49 g/cm³. Further, a rigid urethane foam containing cerium oxide was used as the polishing pad.

After completing the step of correcting surface unevenness, the surface unevenness of the substrate surface was measured and the flatness of the substrate surface was found to be 120 nm, the ten-point average roughness was 4.6 nm and the Rms was 0.34 nm.

### [Step of Finishing Surface Roughness]

The step of finishing surface roughness was performed after completing the step of correcting surface unevenness. The substrate 1 was polished with a second polishing pad while supplying a polishing agent of cerium oxide with an average particle diameter of 0.2 μm being dispersed in water and rotating the second polishing pad at 30 rpm so that the surface load was 60 g/cm² by means of a polishing machine (15B-5P manufactured by Speedfam) for 10 minutes. Further, the second polishing pad consists of the same material as that of the polishing pad used in the step of correcting surface unevenness and the hardness defined by JIS K 6235 of the second polishing pad was 65. A suede pad with a nap layer formed on the surface of an unwoven fabric was used as the second polishing pad.

After completing the step of finishing surface roughness, the surface roughness of the substrate surface was measured and the flatness of the substrate surface was found to be 170 nm, the ten-point average roughness was 5 nm and the Rms was 0.15 nm.

### Examples 2 to 9

The steps in Examples 2 to 9 were performed similarly to Example 1 except for changing the hardness or bulk density of the polishing pad in the step of correcting surface unevenness and changing the hardness or bulk density of the second polishing pad and the polishing time in the step of finishing surface roughness.

### Comparative Examples 1 to 5

The steps in Comparative Examples 1 to 4 were performed as similar to Example 1 except for not performing the step of correcting surface unevenness. In Comparative Example 5, the substrate 1 was polished with a polishing pad with a hardness defined by JIS K 6235 of 67 while supplying cerium oxide with an average particle diameter of 0.2 μm being dispersed in water by means of a polishing machine (15B-5P manufactured by Speedfam) for 20 minutes in the step of correcting surface unevenness. Meanwhile, a rigid urethane foam resin containing cerium oxide particles was used as a polishing pad and its bulk density was 0.38 g/cm³. Meanwhile, “CCZ” in Tables 1 and 2 represents substrates (“CLEARCERAM-Z HS” manufactured by Ohara).

TABLE 1

| | | | Example 1 | Example 2 | Example 3 |
|---|---|---|---|---|---|
| | | Substrate | CCZ | CCZ | CCZ |
| | | Material | | | |
| Step of | Surface | Flatness | 100 | 100 | 100 |
| Modifying | Profile | (PV) (nm) | | | |
| Flatness | after | Ten-Point | 6.5 | 6.7 | 6.8 |
| | Processing | Average | | | |
| | | Roughness | | | |
| | | (nm) | | | |
| | | Rms (nm) | 0.82 | 0.36 | 0.59 |
| | Polishing Pad | | Cerium Oxide- | Cerium Oxide- | Cerium Oxide- |
| | | | Containing Rigid | Containing Rigid | Containing Rigid |
| | | | Urethane Foam | Urethane Foam | Urethane Foam |
| Step of | Hardness (JIS K6253) | | 87 | 79 | 84 |
| Modifying | of Polishing Pad | | | | |
| Surface | Bulk Density of | | 0.49 | 0.4 | 0.45 |
| Unevenness | Polishing Pad (g/cm3) | | | | |
| | Polishing Agent | | Colloidal Silica | Colloidal Silica | Colloidal Silica |
| | Average Particle | | 80 nm | 80 nm | 80 nm |
| | Diameter of Polishing | | | | |
| | Agent | | | | |
| | Processing Pressure | | 50 | 50 | 50 |
| | (g/cm2) | | | | |
| | Processing Time (min) | | 20 | 20 | 20 |
| | Surface | Flatness | 120 | 130 | 140 |
| | Profile | (PV) (nm) | | | |
| | after | Ten-Point | 4.6 | 4.0 | 4.4 |
| | Processing | Average | | | |
| | | Roughness | | | |
| | | (nm) | | | |
| | | Rms (nm) | 0.34 | 0.30 | 0.33 |
| | Polishing Pad | | Suede Pad with | Suede Pad with | Suede Pad with |
| | | | NAP Layer Formed | NAP Layer Formed | NAP Layer Formed |
| | | | on Unwoven | on Unwoven | on Unwoven |
| | | | Fabric | Fabric | Fabric |
| Step of | Hardness (JIS K6253) | | 65 | 50 | 50 |
| Finishing | of Polishing Pad | | | | |
| Surface | Bulk Density of | | 0.3 | 0.3 | 0.3 |
| Roughness | Polishing Pad (g/cm3) | | | | |
| | Polishing Agent | | Cerium Oxide | Cerium Oxide | Cerium Oxide |
| | Average Particle | | 0.2 μm | 0.2 μm | 0.2 μm |
| | Diameter of Polishing | | | | |
| | Agent | | | | |
| | Processing Pressure | | 60 | 60 | 60 |
| | (g/cm2) | | | | |
| | Time (min) | | 10 | 10 | 6 |
| | Surface | Flatness | 170 | 167 | 172 |
| | Profile | (PV) (nm) | | | |
| | after | Ten-Point | 5.0 | 5.9 | 5.2 |
| | Processing | Average | | | |
| | | Roughness | | | |
| | | (nm) | | | |
| | | Rms (nm) | 0.15 | 0.16 | 0.14 |
| | | | Example 4 | Example 5 | Example 6 |
| | | Substrate | CCZ | CCZ | CCZ |
| | | Material | | | |
| Step of | Surface | Flatness | 100 | 100 | 100 |
| Modifying | Profile | (PV) (nm) | | | |
| Flatness | after | Ten-Point | 7.8 | 6.2 | 6.4 |
| | Processing | Average | | | |
| | | Roughness | | | |
| | | (nm) | | | |
| | | Rms (nm) | 0.67 | 0.60 | 0.63 |
| | Polishing Pad | | Cerium Oxide- | Cerium Oxide- | Cerium Oxide- |
| | | | Containing Rigid | Containing Rigid | Containing Rigid |
| | | | Urethane Foam | Urethane Foam | Urethane Foam |
| Step of | Hardness (JIS K6253) | | 86 | 87 | 87 |
| Modifying | of Polishing Pad | | | | |
| Surface | Bulk Density of | | 0.49 | 0.49 | 0.49 |
| Unevenness | Polishing Pad (g/cm3) | | | | |
| | Polishing Agent | | Colloidal Silica | Colloidal Silica | Colloidal Silica |
| | Average Particle | | 80 nm | 100 nm | 120 nm |
| | Diameter of Polishing | | | | |
| | Agent | | | | |
| | Processing Pressure | | 50 | 50 | 50 |
| | (g/cm2) | | | | |
| | Processing Time (min) | | 20 | 20 | 20 |
| | Surface | Flatness | 120 | 140 | 160 |
| | Profile | (PV) (nm) | | | |
| | after | Ten-Point | 4.8 | 4.4 | 4.8 |
| | Processing | Average | | | |
| | | Roughness | | | |
| | | (nm) | | | |
| | | Rms (nm) | 0.34 | 0.30 | 0.33 |
| | Polishing Pad | | Suede Pad with | Suede Pad with | Suede Pad with |
| | | | NAP Layer Formed | NAP Layer Formed | NAP Layer Formed |
| | | | on Unwoven | on Unwoven | on Unwoven |
| | | | Fabric | Fabric | Fabric |
| Step of | Hardness (JIS K6253) | | 50 | 50 | 50 |
| Finishing | of Polishing Pad | | | | |
| Surface | Bulk Density of | | 0.3 | 0.3 | 0.3 |
| Roughness | Polishing Pad (g/cm3) | | | | |
| | Polishing Agent | | Cerium Oxide | Cerium Oxide | Cerium Oxide |
| | Average Particle | | 0.2 μm | 0.2 μm | 0.2 μm |
| | Diameter of Polishing | | | | |
| | Agent | | | | |
| | Processing Pressure | | 60 | 60 | 60 |
| | (g/cm2) | | | | |
| | Time (min) | | 10 | 10 | 6 |
| | Surface | Flatness | 170 | 167 | 172 |
| | Profile | (PV) (nm) | | | |
| | after | Ten-Point | 5.3 | 6.2 | 5.5 |
| | Processing | Average | | | |
| | | Roughness | | | |
| | | (nm) | | | |
| | | Rms (nm) | 0.15 | 0.16 | 0.16 |
| | | | Example 7 | Example 8 | Example 9 |
| | | Substrate | CCZ | CCZ | CCZ |
| | | Material | | | |
| Step of | Surface | Flatness | 100 | 100 | 100 |
| Modifying | Profile | (PV) (nm) | | | |
| Flatness | after | Ten-Point | 6.3 | 7.3 | 7.0 |
| | Processing | Average | | | |
| | | Roughness | | | |
| | | (nm) | | | |
| | | Rms (nm) | 0.77 | 0.43 | 0.56 |
| | Polishing Pad | | Cerium Oxide- | Cerium Oxide- | Cerium Oxide- |
| | | | Containing Rigid | Containing Rigid | Containing Rigid |
| | | | Urethane Foam | Urethane Foam | Urethane Foam |
| Step of | Hardness (JIS K6253) | | 88 | 89 | 87 |
| Modifying | of Polishing Pad | | | | |
| Surface | Bulk Density of | | 0.5 | 0.51 | 0.49 |
| Unevenness | Polishing Pad (g/cm3) | | | | |
| | Polishing Agent | | Colloidal Silica | Colloidal Silica | Colloidal Silica |
| | Average Particle | | 80 nm | 80 nm | 80 nm |
| | Diameter of Polishing | | | | |
| | Agent | | | | |
| | Processing Pressure | | 50 | 50 | 50 |
| | (g/cm2) | | | | |
| | Processing Time (min) | | 20 | 20 | 20 |
| | Surface | Flatness | 120 | 120 | 120 |
| | Profile | (PV) (nm) | | | |
| | after | Ten-Point | 4.6 | 4.6 | 4.6 |
| | Processing | Average | | | |
| | | Roughness | | | |
| | | (nm) | | | |
| | | Rms (nm) | 0.34 | 0.34 | 0.34 |
| | Polishing Pad | | Suede Pad with | Suede Pad with | Suede Pad with |
| | | | NAP Layer Formed | NAP Layer Formed | NAP Layer Formed |
| | | | on Unwoven | on Unwoven | on Unwoven |
| | | | Fabric | Fabric | Fabric |
| Step of | Hardness (JIS K6253) | | 50 | 50 | 50 |
| Finishing | of Polishing Pad | | | | |
| Surface | Bulk Density of | | 0.3 | 0.3 | 0.3 |
| Roughness | Polishing Pad (g/cm3) | | | | |
| | Polishing Agent | | Cerium Oxide | Cerium Oxide | Cerium Oxide |
| | Average Particle | | 0.4 μm | 0.6 μm | 0.8 μm |
| | Diameter of Polishing | | | | |
| | Agent | | | | |
| | Processing Pressure | | 60 | 60 | 60 |
| | (g/cm2) | | | | |
| | Time (min) | | 10 | 6 | 6 |
| | Surface | Flatness | 170 | 170 | 170 |
| | Profile | (PV) (nm) | | | |
| | after | Ten-Point | 5.0 | 5.0 | 5.0 |
| | Processing | Average | | | |
| | | Roughness | | | |
| | | (nm) | | | |
| | | Rms (nm) | 0.17 | 0.18 | 0.19 |

TABLE 2

| | | | Comparative | Comparative | Comparative |
|---|---|---|---|---|---|
| | | | Example 1 | Example 2 | Example 3 |
| | | Substrate | CCZ | CCZ | CCZ |
| | | Material | | | |
| Step of | Surface | Flatness | 100 | 100 | 100 |
| Modifying | Profile | (PV) (nm) | | | |
| Flatness | after | Ten-Point | 6.5 | 6.7 | 6.8 |
| | Processing | Average | | | |
| | | Roughness | | | |
| | | (nm) | | | |
| | | Rms (nm) | 0.82 | 0.36 | 0.59 |
| | Polishing Pad | | — | — | — |
| Step of | Hardness (JIS K6253) | | — | — | — |
| Modifying | of Polishing Pad | | | | |
| Surface | Bulk Density of | | — | — | — |
| Unevenness | Polishing Pad (g/cm3) | | | | |
| | Polishing Agent | | — | — | — |
| | Average Particle | | — | — | — |
| | Diameter of Polishing | | | | |
| | Agent | | | | |
| | Processing Pressure | | — | — | — |
| | (g/cm2) | | | | |
| | Time (min) | | — | — | — |
| | Surface | Flatness | — | — | — |
| | Profile | (PV) (nm) | | | |
| | after | Ten-Point | — | — | — |
| | Processing | Average | | | |
| | | Roughness | | | |
| | | (nm) | | | |
| | | Rms (nm) | — | — | — |
| | Polishing Pad | | Cerium Oxide- | Suede Pad with | Cerium Oxide- |
| | | | Containing Rigid | NAP Layer Formed | Containing Rigid |
| | | | Urethane Foam | on Unwoven | Urethane Foam |
| | | | | Fabric | |
| Step of | Hardness (JIS K6253) | | 87 | 50 | 84 |
| Finishing | of Polishing Pad | | | | |
| Surface | Bulk Density of | | 0.49 | 0.3 | 0.45 |
| Roughness | Polishing Pad (g/cm3) | | | | |
| | Polishing Agent | | Cerium Oxide | Cerium Oxide | Colloidal Silica |
| | Average Particle | | 0.2 μm | 0.2 μm | 80 nm |
| | Diameter of Polishing | | | | |
| | Agent | | | | |
| | Processing Pressure | | 40 | 40 | 40 |
| | (g/cm2) | | | | |
| | Time (min) | | 20 | 10 | 20 |
| | Surface | Flatness | 300 | 140 | 250 |
| | Profile | (PV) (nm) | | | |
| | after | Ten-Point | 11.8 | 13.2 | 12.8 |
| | Processing | Average | | | |
| | | Roughness | | | |
| | | (nm) | | | |
| | | Rms (nm) | 0.22 | 0.35 | 0.23 |

| | | | Comparative | Comparative |
|---|---|---|---|---|
| | | | Example 4 | Example 5 |
| | | Substrate | CCZ | CCZ |
| | | Material | | |
| Step of | Surface | Flatness | 100 | 100 |
| Modifying | Profile | (PV) (nm) | | |
| Flatness | after | Ten-Point | 7.8 | 6.4 |
| | Processing | Average | | |
| | | Roughness | | |
| | | (nm) | | |
| | | Rms (nm) | 0.67 | 0.63 |
| | Polishing Pad | | — | Cerium Oxide- |
| | | | | containing Rigid |
| | | | | Urethane Foam |
| Step of | Hardness (JIS K6253) | | — | 67 |
| Modifying | of Polishing Pad | | | |
| Surface | Bulk Density of | | — | 0.38 |
| Unevenness | Polishing Pad (g/cm3) | | | |
| | Polishing Agent | | — | Cerium Oxide |
| | Average Particle | | — | 0.2 μm |
| | Diameter of Polishing | | | |
| | Agent | | | |
| | Processing Pressure | | — | 40 |
| | (g/cm2) | | | |
| | Time (min) | | — | 20 |
| | Surface | Flatness | — | 300 |
| | Profile | (PV) (nm) | | |
| | after | Ten-Point | — | 12.0 |
| | Processing | Average | | |
| | | Roughness | | |
| | | (nm) | | |
| | | Rms (nm) | — | 0.20 |
| | Polishing Pad | | Suede Pad with | Suede Pad with |
| | | | NAP Layer Formed | NAP Layer Formed |
| | | | on Unwoven | on Unwoven |
| | | | Fabric | Fabric |
| Step of | Hardness (JIS K6253) | | 50 | 50 |
| Finishing | of Polishing Pad | | | |
| Surface | Bulk Density of | | 0.3 | 0.3 |
| Roughness | Polishing Pad (g/cm3) | | | |
| | Polishing Agent | | Colloidal Silica | Colloidal Silica |
| | Average Particle | | 80 nm | 80 nm |
| | Diameter of Polishing | | | |
| | Agent | | | |
| | Processing Pressure | | 40 | 100 |
| | (g/cm2) | | | |
| | Time (min) | | 10 | 6 |
| | Surface | Flatness | 250 | 170 |
| | Profile | (PV) (nm) | | |
| | after | Ten-Point | 12.1 | 11.8 |
| | Processing | Average | | |
| | | Roughness | | |
| | | (nm) | | |
| | | Rms (nm) | 0.39 | 0.17 |

It will be appreciated from the Table 1 that a substrate with an excellent flatness, a smooth surface roughness and no unevenness, that is to say a substrate with an excellent flatness and a small degree of ten-point average roughness and Rms can be supplied by the method of fabricating a substrate according to the present invention.

It will also be appreciated from the Table 2 that the substrates in Comparative Examples 1 to 5 contain unevenness.

1. A method of fabricating a substrate comprising: a step of correcting flatness; a step of correcting surface unevenness wherein the substrate surface is polished by means of a polishing pad with a hardness defined by JIS K 6253 of 70 or more; and a step of finishing surface roughness.

2. The method of fabricating a substrate according to claim 1, wherein the main material of the polishing pad is one of a resin, an unwoven fabric and an unwoven fabric impregnated with a resin.

3. The method of fabricating a substrate according to claim 2, wherein inorganic particles are dispersed in the main material of the polishing pad.

4. The method of fabricating a substrate according to claim 1, wherein the bulk density of the polishing pad is 0.2 g/cm3 or more.

5. The method of fabricating a substrate according to claim 1, wherein a polishing agent with an average particle diameter of 1 μm or less is used in the step of correcting surface unevenness.

6. The method of fabricating a substrate according to claim 1, wherein the ten-point average roughness of the substrate surface after the step of correcting surface unevenness is 6.5 nm or less.

7. The method of fabricating a substrate according to claim 1, wherein the flatness of the substrate surface after the step of correcting flatness is 1,000 nm or less.

8. The method of fabricating a substrate according to claim 1, wherein polishing is performed so that the surface load of the substrate surface is 80 g/cm2 or less in the step of finishing surface roughness.

9. The method of fabricating a substrate according to claim 1, wherein the step of correcting flatness is a step of polishing the substrate surface by means of a magnetic fluid containing abrasive polishing particles.

10. The method of fabricating a substrate according to claim 1, wherein the substrate comprises one of a glass and a glass ceramic.

11. A substrate obtained by the method of fabricating a substrate according to claim 1, wherein at least one surface has a surface profile with a flatness of 1,000 nm or less, a ten-point average roughness of 10 nm or less and a Rms of 1 nm or less.

12. A semiconductor exposure mask using a substrate fabricated by the method of fabricating a substrate according to claim 1.

13. A semiconductor exposure mirror using a substrate fabricated by a method of fabricating a substrate according to claim 1.

14. A disc for flying height testing of hard-disk magnetic heads using a substrate fabricated by a method of fabricating a substrate according to claim 1.

15. A substrate for pharmaceutical testing using a substrate fabricated by the method of fabricating a substrate according to claim 1.
